(19) United States
(12) Patent Application Publication
(10) Pub. No.: US 2007/0066000 A1
(43) Pub. Date: Mar. 22, 2007

(54) Method of manufacturing a semiconductor device

(75) Inventor: Satoru Muramatsu, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, Kanagawa (JP)

(21) Appl. No.: 11/523,688

(22) Filed: Sep. 20, 2006

(30) Foreign Application Priority Data
Sep. 21, 2005 (JP) 2005-273656

(51) Int. Cl. H01L 21/8234

(52) U.S. Cl. 438/197

(57) ABSTRACT

A method of manufacturing a semiconductor device including an elevated source/drain structure that can suppress emergence of a junction leak current. The method includes forming a trench on a predetermined position on a surface of a semiconductor substrate, forming an isolation layer so as to fill the trench, and so as to protrude from the surface of the semiconductor substrate, forming a film so as to cover the semiconductor substrate and the isolation layer, selectively removing the film thus to form a cover layer on a lateral portion of the isolation layer exposed on the semiconductor substrate, forming a gate electrode unit on the semiconductor substrate, forming an epitaxial layer in a region between the cover layer and the gate electrode unit on the surface of the semiconductor substrate 102, and forming a silicide layer at least on part of the epitaxial layer.

This application is based on Japanese patent application NO.2005-273656, the content of which is incorporated hereinto by reference.

### BACKGROUND

1. Technical Field

The present invention relates to a method of manufacturing a semiconductor device that includes an elevated source/drain structure.

2. Related Art

In conventional semiconductor devices, an extension region is formed in a shallow portion of a semiconductor substrate, to thereby improve a short channel characteristic. Also, to reduce resistance in a source/drain region, a silicide layer is provided on the source/drain region. When, however, the junction depth (depth of the high-concentration Si layer) below the silicide layer is insufficient, a junction leak current drastically increases. Accordingly, techniques conventionally known in this connection include carrying out a selective epitaxial growth on the source/drain region to form an elevated source/drain structure, to thereby not only improve the short channel characteristic but also reduce the junction leak current (for example, S. S. Wong et al. “Elevated Source/Drain MOSFET”, IEDM Tech. Dig., p 634, 1984).

A method of manufacturing the semiconductor device in which the foregoing technique is introduced is found, for example, in JP-A No.H11-354784. According to the manufacturing method disclosed therein, an epitaxial layer is first formed between an isolation layer and a gate electrode unit on a semiconductor substrate. Then a polysilicon layer is formed so as to fill a recess between the isolation layer and the epitaxial layer.

Another method of manufacturing such semiconductor device is found in JP-A No.2000-31480. FIGS. 5A to 6B are cross-sectional views showing a manufacturing process of the semiconductor device disclosed in this document.

According to the method disclosed therein, firstly an isolation layer 206 is formed so as to fill a trench provided on a semiconductor substrate 202, and so as to protrude from a surface of the semiconductor substrate 202 (FIG. 5A). Then a gate dielectric film 212 and a gate electrode 216 are formed by a known method. After forming the gate electrode 216, an ion implantation process is performed utilizing the gate electrode 216 as the mask, to thereby form extension regions 218, 219 on the surface of the semiconductor substrate 202. After forming an insulating layer (not shown) so as to cover the entire substrate, an etch-back process is performed to form a sidewall 222 along a lateral portion of the gate electrode 216. Through such steps, a gate electrode unit 213 including the gate dielectric film 212, the gate electrode 216, and the sidewall 222 is formed (FIG. 5B). In addition, the etching process to form the sidewall 222 leads to formation of a recess 206a along a lateral portion of the isolation layer 206.

Then an insulating layer (not shown) is formed so as to cover the semiconductor substrate 202, the gate electrode unit 213, and the isolation layer 206. The insulating layer is then selectively removed by using anisotropic dry etching (for example), thus to form a cover layer 210 on the recess 206a of the isolation layer 206 exposed on the semiconductor substrate 202 (FIG. 5C).

An epitaxial layer 214 is then formed in a region between the cover layer 210 and the gate electrode unit 213 on the surface of the semiconductor substrate 202 (FIG. 6A). On the surface of the epitaxial layer 214 and of the gate electrode 216, a silicide layer 230 is formed (FIG. 6B). This is followed by a known manufacturing process of an ordinary CMOS semiconductor, thus to manufacture the semiconductor device.

Thus, the feature of the method of manufacturing the semiconductor device disclosed in JP-A No.2000-31480 lies in forming the cover layer 210 along the lateral portion of the isolation layer 206, immediately before forming the epitaxial layer 214. Forming the cover layer 210 in advance allows planarizing the exposed surface of the semiconductor substrate 202, thereby facilitating the epitaxial layer formed on the surface to grow at a uniform speed, thus resulting in formation of the epitaxial layer 214 in a uniform thickness. JP-A No.2000-31480 states that forming the silicide layer 230 in a uniform thickness on the epitaxial layer 214 thus formed leads to a reduction in junction leak current.

From such viewpoint, it is desirable to form the cover layer 210 for the isolation layer 206 after forming the gate electrode unit 213, to thereby prevent the cover layer 210 from being damaged by the etching process or the like. In other words, if the cover layer 210 were formed before forming the gate electrode unit 213, the cover layer 210 would be damaged through the formation of the sidewall 222, which would impede forming the silicide layer 230 in a uniform thickness.

In addition, JP-A No.2000-260952 discloses a method of manufacturing a semiconductor device including forming a buried isolation layer in a semiconductor substrate, and then forming a stopper insulating layer on the isolation layer, so as to protrude from a surface of the semiconductor substrate.

It has been discovered, however, that the conventional techniques according to the foregoing documents have a room of improvement in the following aspects.

Firstly, in the techniques according to JP-A No.H11-354784 and JP-A No.2000-31480, since the bottom of the silicide layer 230 is located close to the bottom of the joint part as shown in FIG. 6B, the leak current increases at the approximate position of these. Therefore, the techniques may still incur emergence of a junction leak current.

Secondly, the technique according to JP-A No.2000-260952 requires forming the buried isolation layer in the semiconductor substrate, and then forming the stopper insulating layer on the isolation layer, so as to protrude from the surface of the semiconductor substrate, which complicates the manufacturing process.

### SUMMARY OF THE INVENTION

The present inventors have discovered that, in order to minimize the junction leak current among the foregoing problems, the manufacturing methods according to JP-A No.H11-354784 and JP-A No.2000-31480 are not fully satisfactory yet, but a measure has to be taken to prevent the formation of the recess along the lateral portion of the isolation layer.

Specifically, if the isolation layer is already formed at the time of forming the sidewall along the lateral portion of the gate electrode, the entire isolation layer is subjected to the dry etching process. Accordingly, the recess (also called a divot) is formed on the lateral portion of the isolation layer, such that a surface of the semiconductor substrate is exposed in the trench in which the isolation layer is buried. Forming the cover layer on the lateral portion of the isolation layer under such state leads to formation of a gap between the semiconductor substrate and the isolation layer, for example as shown in FIG. 7. As a result, the silicide layer intrudes into the gap upon being formed, thereby provoking emergence of the junction leak current.

The present invention has been conceived in view of the foregoing situation, to provide the following.

According to the present invention, there is provided a method of manufacturing a semiconductor device, comprising:

forming a trench at a predetermined position on a surface of a semiconductor substrate,

forming an isolation layer so as to fill the trench, and so as to protrude from the surface of the semiconductor substrate,

forming a film so as to cover the semiconductor substrate and the isolation layer,

selectively removing the film thus to form a cover layer on a lateral portion of the isolation layer exposed on the semiconductor substrate,

forming a gate electrode unit on the semiconductor substrate,

forming an epitaxial layer in a region between the cover layer and the gate electrode unit on the surface of the semiconductor substrate, and

forming a silicide layer at least on a part of the epitaxial layer.

The method thus arranged allows preventing formation of a recess on a lateral portion of the isolation layer, by such a simple process as forming the cover layer on the lateral portion of the isolation layer before forming the gate electrode unit. Such method facilitates forming the silicide layer in a uniform thickness (structure depth), thus achieving the method of manufacturing a semiconductor device that can suppress emergence of a junction leak current.

Thus, the present invention provides a method of manufacturing a semiconductor device including an elevated source/drain structure that can suppress emergence of a junction leak current.

### BRIEF DESCRIPTION OF THE DRAWINGS

The above and other objects, advantages and features of the present invention will be more apparent from the following description taken in conjunction with the accompanying drawings, in which:

FIGS. 1A to 1C are schematic cross-sectional views sequentially showing a manufacturing process of a semiconductor device according to an embodiment of the present invention;

FIGS. 2A to 2C are schematic cross-sectional views sequentially showing a manufacturing process of a semiconductor device according to the embodiment;

FIGS. 3A to 3C are schematic cross-sectional views sequentially showing a manufacturing process of a semiconductor device according to the embodiment;

FIGS. 4A and 4B are schematic cross-sectional views sequentially showing a manufacturing process of a semiconductor device according to the embodiment;

FIGS. 5A to 5C are schematic cross-sectional views sequentially showing a conventional manufacturing process of a semiconductor device;

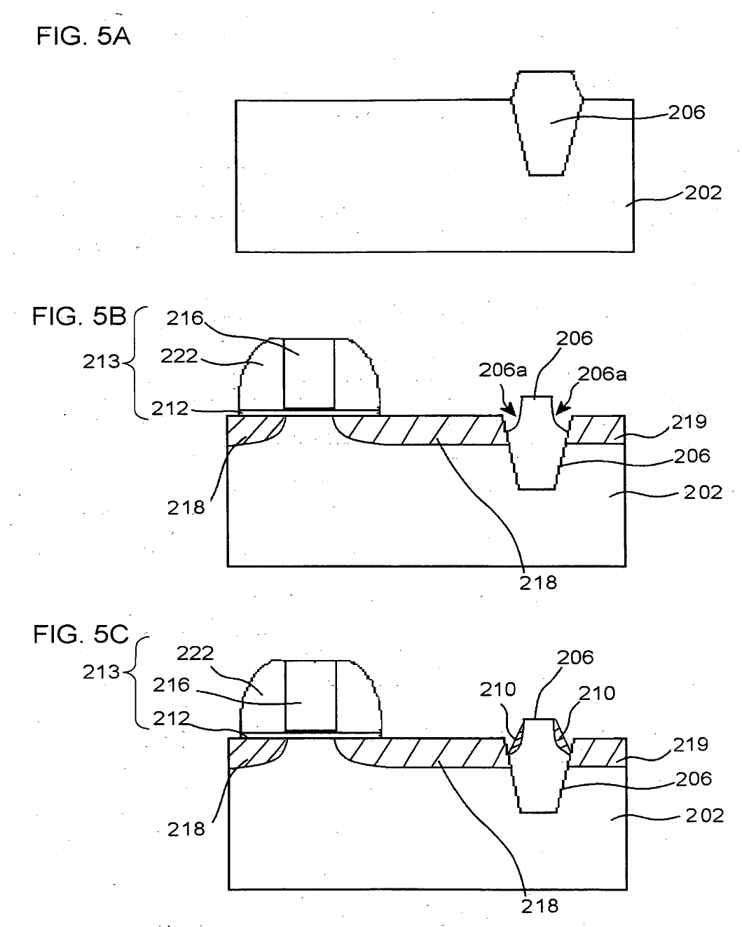

FIGS. 6A and 6B are schematic cross-sectional views sequentially showing a conventional manufacturing process of a semiconductor device; and

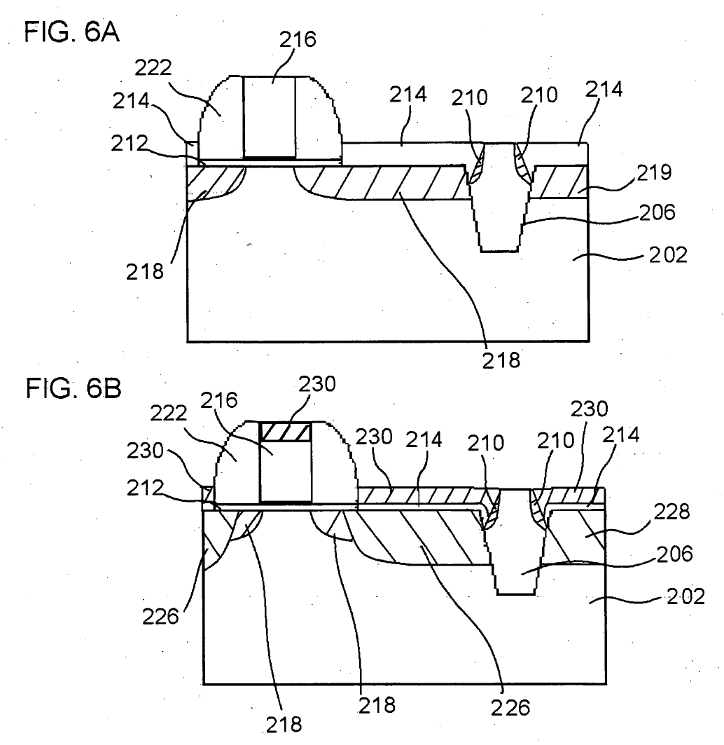

FIG. 7 is an enlarged fragmentary cross-sectional view showing an isolation layer involved in the conventional manufacturing process of a semiconductor device.

### DETAILED DESCRIPTIONS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereunder, an embodiment of the present invention will be described referring to the accompanying drawings. In all the drawings, same constituents are given the same numerals, and the description thereof will not be repeated.

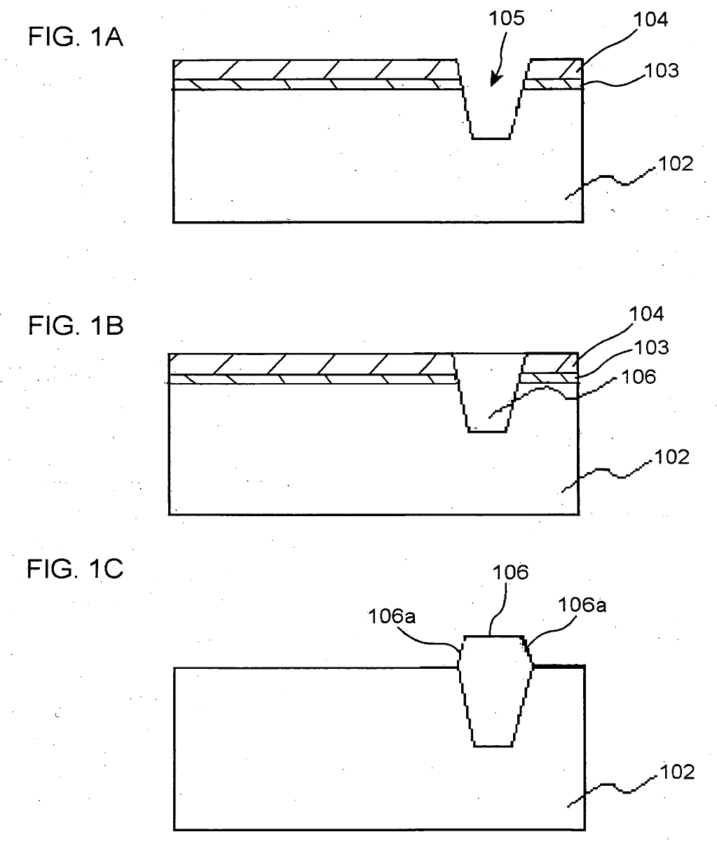

A method of manufacturing a semiconductor device according to this embodiment includes the following steps, as shown in FIGS. 1A through 4B.

(i) Forming a trench 105 on a predetermined position on a surface of a semiconductor substrate 102 (FIG. 1A).

(ii) Forming an isolation layer 106 so as to fill the trench, and so as to protrude from the surface of the semiconductor substrate 102 (FIGS. 1B and 1C).

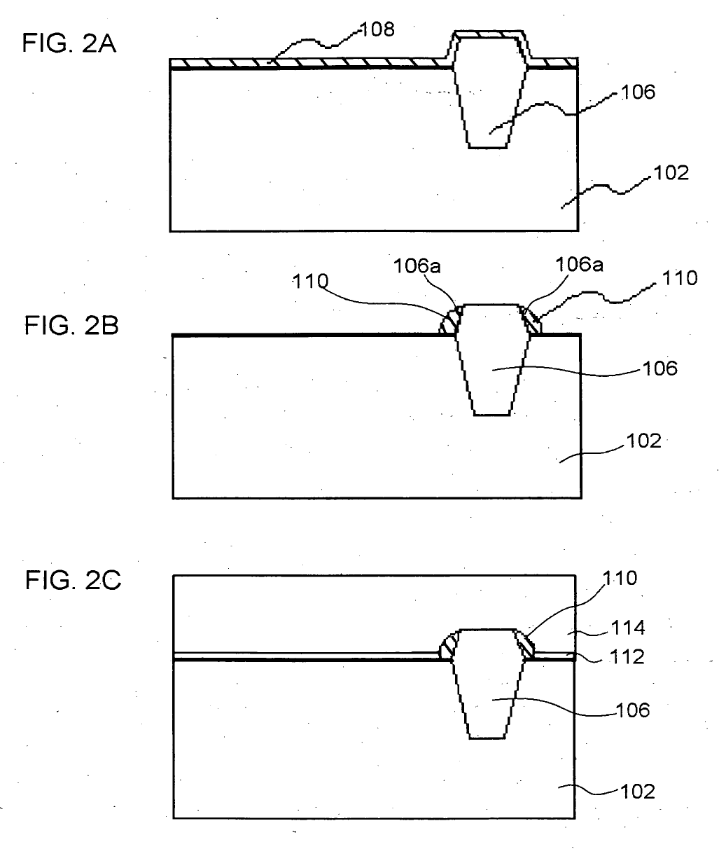

(iii) Forming a film 108 so as to cover the semiconductor substrate 102 and the isolation layer 106 (FIG. 2A).

(iv) Selectively removing the film 108 by using anisotropic dry etching(for example) thus to form a cover layer 110 on a lateral portion 106a of the isolation layer 106 exposed on the semiconductor substrate 102 (FIG. 2B)

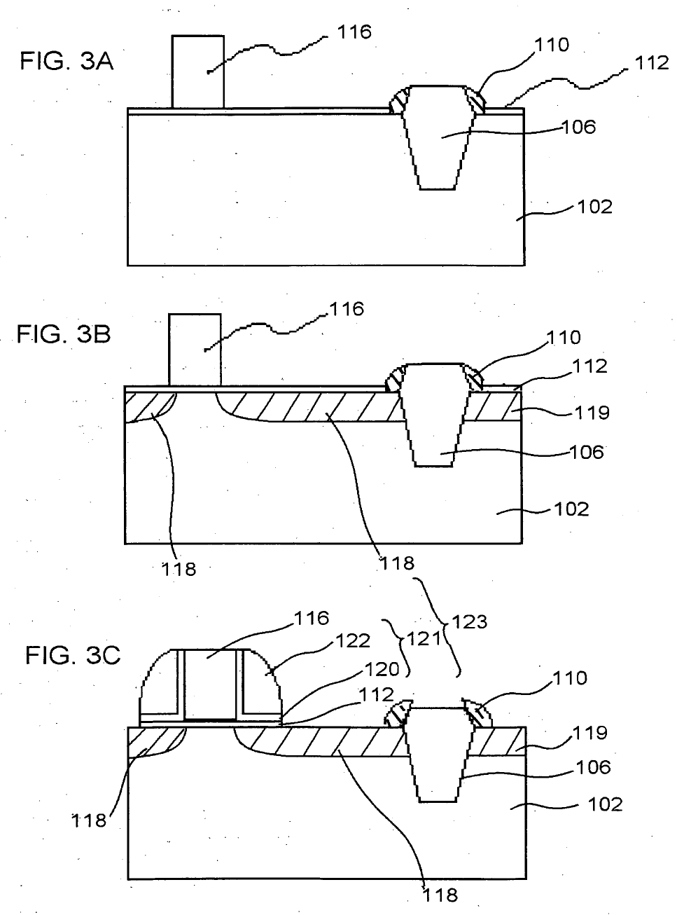

(v) Forming a gate electrode unit 123 on the semiconductor substrate 102 (FIGS. 2C to 3C).

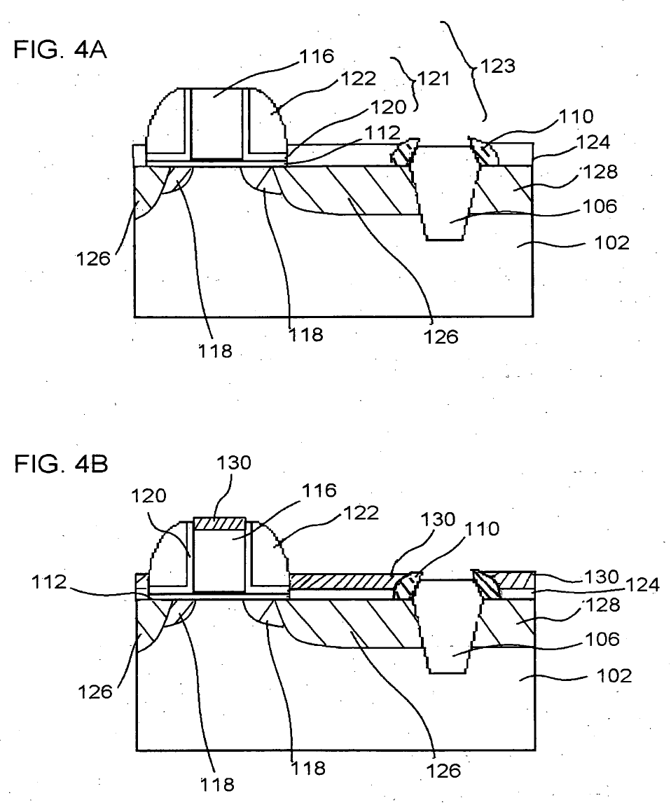

(vi) Forming an epitaxial layer 124 in a region between the cover layer 110 and the gate electrode unit 123 on the surface of the semiconductor substrate 102 (FIG. 4A).

(vii) Forming a silicide layer 130 at least on a part of the epitaxial layer 124 (FIG. 4B).

The method of manufacturing a semiconductor device according to this embodiment will be described in further details along the foregoing steps by turns.

Firstly, the trench 105 is formed on a predetermined position on a surface of the semiconductor substrate 102 (FIG. 1A).

Specifically, silicon oxide layer 103 and a silicon nitride layer 104 are sequentially formed on the semiconductor substrate 102. Method of forming the silicon oxide layer 103 includes performing chemical vapor deposition (hereinafter, CVD) on the semiconductor substrate 102. In addition, in the case of silicon substrate, method of forming the silicon oxide layer 103 includes thermally oxidizing the silicon substrate. The silicon nitride layer 104 may be constituted of SiN or Si₃N₄, and may be formed by a CVD process.

A resist layer (not shown) is then formed on the silicon nitride layer 104, and an opening is formed at a predetermined position through an ordinary lithography process. The resist layer is utilized as the mask for forming an opening in the oxide layer 103 and the silicon nitride layer 104, and further the trench 105 is formed on the semiconductor substrate 102 (FIG. 1A).

Then the isolation layer 106 is formed so as to fill the trench 105 formed on the semiconductor substrate 102, and so as to protrude from the surface of the semiconductor substrate 102 by using CVD process and CMP process and the like (FIGS. 1B and 1C).

Specifically, an insulating layer (not shown) is formed so as to fill the trench 105 and to cover the surface of the silicon nitride layer 104. The insulating layer may be formed by a CVD process. The insulating layer may be constituted of SiO₂ or SiN.

An ordinary stripping process is carried out to remove the insulating layer on the silicon nitride layer 104, leaving the insulating layer only in the trench 105, thus to form the isolation layer 106 (FIG. 1B).

Then an ordinary wet etching process is carried out to remove the silicon nitride layer 104 and the oxide layer 103. As a result, the isolation layer 106 that fills the trench 105 and protrudes from the surface of the semiconductor substrate 102 is obtained (FIG. 1C). The wet etching process also removes a topmost portion of the isolation layer 106, thereby forming a lateral portion 106a.

The height (herein also called protrusion amount) of the isolation layer 106 from the surface of the semiconductor substrate 102 may be made lower than in the conventional semiconductor device. To be more detailed, during the conventional process of forming the cover layer 210, the height of the isolation layer 206 is reduced by the etch-back process to form the gate electrode unit 213. Accordingly, in order to secure a predetermined height of the cover layer 210, the isolation layer 206 has to be formed taking into consideration the reduction in height thereof because of the etch-back process. Increasing thus the protrusion amount of the isolation layer 206 incurs a loss in Depth of Field (hereinafter abbreviated as DOF) between the isolation layer 206 and the semiconductor substrate 202, in the exposure process to form the gate electrode 216.

In contrast, the cover layer 110 is formed before forming the gate electrode unit 123 in this embodiment, which eliminates the need to take into account the reduction in height of the isolation layer 106 due to the etch-back process. Besides, since the isolation layer 106 may be formed with a less protrusion amount than in the conventional device, the loss in DOF between the isolation layer 106 and the semiconductor substrate 102 is minimized, in the exposure process to form the gate electrode 116. Further, forming the cover layer 110 before the formation of the gate electrode unit 123 allows granting the cover layer 110 with a milder slope profile than the conventional cover layer 210 formed on the recess 206a on the lateral portion of the isolation layer 206. Consequently, the loss in DOF can be further minimized.

Thus, the height of the isolation layer 106 from the surface of the semiconductor substrate 102 may be higher than the thickness of the epitaxial layer 124, specifically in a range of 1.5 nm to 450 nm, for example.

Then a film 108 is formed so as to cover the semiconductor substrate 102 and the isolation layer 106 (FIG. 2A).

Specifically, a thermal oxidation (silicon substrate case) or a CVD process (semiconductor substrate case) is carried out to form an oxide layer (not shown) so as to cover the semiconductor substrate 102 and the isolation layer 106. Further, an ion implantation is performed to thereby form a well in a desired region on the semiconductor substrate 102, and an impurity for controlling a threshold voltage (Vt) is doped.

After removing the oxide layer, the film 108 is formed so as to cover the semiconductor substrate 102 and the isolation layer 106 (FIG. 2A). The film 108 may contain Si and N, and may specifically be constituted of SiN or Si₃N₄. Providing such film 108 allows easily differentiating the anisotropic dry etching rate from a first insulating layer 120 and a second insulating layer 122, in an etching process to form the gate electrode unit 123 to be subsequently described, thereby preventing the film 108 from being removed by the etching.

Then an etch-back process is performed to selectively remove the film 108 such that a portion thereof remains on the lateral portion 106a of the isolation layer 106 exposed on the semiconductor substrate 102, thus to form the cover layer 110 (FIG. 2B). Forming the cover layer 110 before forming the gate electrode unit 123 to be described later allows protecting the isolation layer 106 from the effect of the etching process performed to form the gate electrode unit 123. Also, the cover layer 110 is formed so as to be in contact with the surface of the lateral portion 106a and the semiconductor substrate 102. Such formation process prevents formation of a gap on the surface of the semiconductor substrate 102 unlike the conventional technique, thereby facilitating forming a silicide layer 130 to be described later in a uniform thickness (structure depth). Consequently, emergence of the junction leak current can be suppressed.

Further, the height of the cover layer 110 from the surface of the semiconductor substrate 102 is generally the same as the height of the isolation layer 106 from the surface of the semiconductor substrate 102. In this embodiment, since the cover layer 110 is formed before forming the gate electrode unit 123, the cover layer 110 may be formed in a predetermined height without take into account the reduction in height of the isolation layer 106 due to the etching process. The cover layer 110 may be formed in a height of 1.5 nm to 450 nm from the surface of the semiconductor substrate 102.

Now the gate electrode unit 123 is formed on the semiconductor substrate 102 (FIGS. 2C to 3C).

Specifically, a gate dielectric film 112 is first formed on the semiconductor substrate 102 by a known method, and a polycrystalline silicon layer 114 is formed on the gate dielectric film 112 (FIG. 2C). Then an etching process is performed so as to shape the polycrystalline silicon layer 114 in a predetermined pattern, thus to form the gate electrode 116 (FIG. 3A).

A resist layer (not shown) is then formed so as to cover a P-type MOS transistor formation region. The resist layer covering the gate electrode 116, the isolation layer 106 and cover layer 110, and the P-type MOS transistor formation region resist layer is utilized as the mask for doping an N-type impurity such as Sb or As onto the surface layer of the semiconductor substrate 102. This process leads to formation of a pair of first extension regions 118 (FIG. 3B). Further, the resist layer covering the P-type MOS transistor formation region is removed, and a resist layer (not shown) is formed so as to cover an N-type MOS-type MOS transistor formation region. Through a similar process, a P-type impurity such as B is doped onto the surface layer of the semiconductor substrate 102 in the P-type MOS transistor formation region, to thereby form a pair of second extension regions 119 (FIG. 3B).

Then the resist layer covering the N-type MOS transistor formation region is removed, and a first insulating layer and a second insulating layer are stacked so as to cover the gate dielectric film 112, the gate electrode 116, the cover layer 110, and the isolation layer 106 by a CVD process. The first insulating layer may be constituted of a silicon oxide layer. The second insulating layer may be constituted of a silicon nitride layer or a silicon oxide layer.

The insulating layers are then subjected to an etch-back process, so as to form a sidewall 121 including a first insulating layer 120 having an L-shaped cross-section and formed on the gate dielectric film 112 and the lateral portion of the gate electrode 116, and a second insulating layer 122 having a generally sector-shaped cross-section and formed so as to cover the surface of the first insulating layer 120. At this stage, the gate electrode unit 123 including the gate dielectric film 112, the gate electrode 116 and the sidewall 121 is obtained (FIG. 3C).

In this embodiment, the first insulating layer 120 and the second insulating layer 122 may be constituted of a material such as SiO₂, which has a different etching rate from that of the cover layer 110. Such structure protects the cover layer 110 from the effect of the etching process performed on the first insulating layer 120 and the second insulating layer 122, thus facilitating determining the protrusion amount of the cover layer 110 as desired.

The epitaxial layer 124 is then formed in a region between the cover layer 110 and the gate electrode unit 123 on the surface of the semiconductor substrate 102 (FIG. 4A).

Specifically, after the formation of the gate electrode unit 123, the semiconductor substrate 102 is dipped in a cleaning solution thus to remove the surface oxide layer on the semiconductor substrate 102. Diluted hydrogen fluoric acid (HF) may be employed as the cleaning solution. In this embodiment, the cover layer 110 is constituted of a compound containing Si and N, which has etching resistance against such type of cleaning solution.

Then a known selective epitaxial growth process is employed so as to form the epitaxial layer 124 on the surface of the semiconductor substrate 102 exposed between the cover layer 110 and the gate electrode unit 123. In addition, an illustration of the epitaxial layer formed in the upper part of the gate electrode 116 and the like is omitted. As a specific example, the epitaxial layer 124 may be formed in a height of 1 nm to 300 nm from the surface of the semiconductor substrate 102.

The epitaxial layer 124 may be formed so that the height of the epitaxial layer 124 from the surface of the semiconductor substrate 102 is lower than the height of the cover layer 110 from the surface of the semiconductor substrate 102. A difference of 0.5 nm to 50 nm in height may be provided between the epitaxial layer 124 and the cover layer 110. Such structure inhibits the epitaxial layer 124 from mutually contacting over the isolation layer 106, thus inhibiting electrical conduction therebetween. Consequently, a short circuit between adjacent transistors, as well as emergence of the junction leak current can be suppressed.

A resist layer (not shown) is then formed so as to cover the P-type MOS transistor formation region. The resist layer covering the gate electrode unit 123, the isolation layer 106 and cover layer 110, and the P-type MOS transistor formation region resist layer is utilized as the mask for doping an N-type impurity such as Sb or As onto the surface layer of the semiconductor substrate 102. This process leads to formation of a pair of first source/drain regions 126 (FIG. 4A). Further, the resist layer covering the P-type MOS transistor formation region is removed, and a resist layer (not shown) is formed so as to cover the N-type MOS transistor formation region. Through a similar process, a P-type dopant atom such as B is doped onto the surface layer of the semiconductor substrate 102 in the P-type MOS transistor formation region, to thereby form a pair of second source/drain regions 128. After removing the resist layer covering the N-type MOS transistor formation region, the impurity in a diffusion layer is activated by an annealing process (FIG. 4A).

Now the silicide layer 130 is formed on the surface of the epitaxial layer 124 and of the gate electrode 116 (FIG. 4B). Suitable materials of the silicide layer 130 include nickel silicide and cobalt silicide.

The above is followed by an ordinary manufacturing process of a CMOS device, so as to fabricate the semiconductor device.

The foregoing embodiment offers the following advantages.

By the method of manufacturing a semiconductor device according to this embodiment, since the cover layer provided on the lateral portion of the isolation layer is formed before the formation of the gate electrode unit, the isolation layer is protected from being damaged during the formation process of the gate electrode unit. Such arrangement therefore prevents formation of a recess (divot) on the lateral portion of the isolation layer, thereby facilitating formation of the silicide layer in a uniform thickness (structure depth) and thus minimizing emergence of the junction leak current.

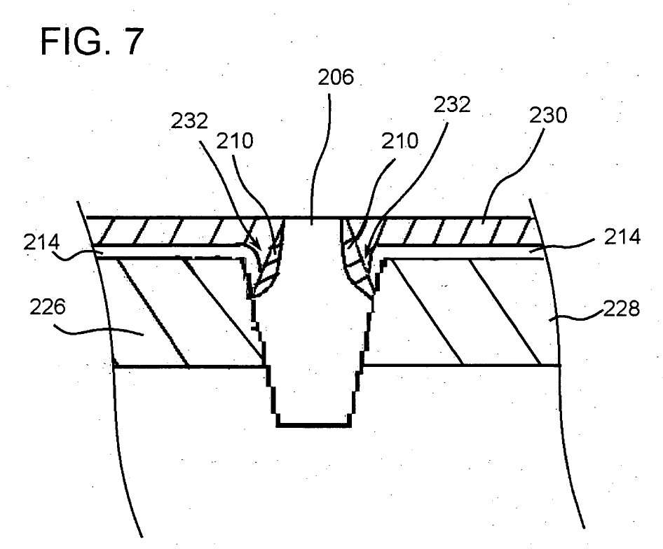

The method of manufacturing a semiconductor device according to the foregoing JP-A No.2000-31480 specifies forming the cover layer 210 on the lateral portion of the isolation layer 206 immediately before forming the epitaxial layer 214. In this process, the isolation layer 206 is not yet protected by the cover layer 210 when the gate electrode unit 213 is about to be formed, and hence the recess 206a is formed on the isolation layer 206, which impedes forming the silicide layer in a uniform thickness. Therefore, although the cover layer 210 is formed on the lateral portion of the isolation layer 206 after the formation process of the gate electrode unit 213, a gap 232 is formed between the semiconductor substrate 202 and the isolation layer 206, as shown in FIG. 7. The silicide layer 230 is hence formed so as to intrude into the gap 232, which still leaves the issue of the junction leak current unsolved.

In contrast, the method of manufacturing a semiconductor device according to the foregoing embodiment allows forming the silicide layer 130 in a uniform thickness, by such a simple process as forming the cover layer 110 provided on the lateral portion 106a of the isolation layer 106 before forming the gate electrode unit 123. Therefore, the method of manufacturing a semiconductor device that can suppress emergence of a junction leak current can be attained.

In the foregoing embodiment, also, the cover layer 110 is formed before forming the gate electrode unit 123 in this embodiment, which eliminates the need to take into account the reduction in height of the isolation layer 106 due to the etch-back process. Besides, since the isolation layer 106 may be formed with a less protrusion amount than in the conventional device, the loss in DOF between the isolation layer 106 and the semiconductor substrate 102 is minimized, in the exposure process to form the gate electrode 116. Further, forming the cover layer 110 before the formation of the gate electrode unit 123 allows granting the cover layer 110 with a milder slope profile than the conventional cover layer 210 formed on the recess 206a on the lateral portion of the isolation layer 206. Consequently, the loss in DOF can be further minimized.

In the foregoing embodiment, the epitaxial layer 124 is formed so that the height of the epitaxial layer 124 from the surface of the semiconductor substrate 102 is lower than the height of the cover layer 110 from the surface of the semiconductor substrate 102

Such structure inhibits the epitaxial layer 124 from mutually contacting over the isolation layer 106, thus inhibiting electrical conduction therebetween. Consequently, a short circuit between adjacent transistors, as well as emergence of the junction leak current can be suppressed.

Further in the foregoing embodiment, the film 108 may contain Si and N.

Providing such film 108 allows easily differentiating the etching rate from the first insulating layer 120 and the second insulating layer 122, in an etching process to form the gate electrode unit 123.

The film 108 is also etching-resistant in a cleaning solution such as diluted HF employed for removing the surface oxide layer of the semiconductor substrate 102. Thus, since the film 108 is resistant against the removing effect of the etching performed in the manufacturing process of the semiconductor device, formation of a recess on the isolation layer 106 is suppressed. Such arrangement therefore facilitates forming the silicide layer 130 in a uniform thickness on the semiconductor substrate 102, and thus suppressing emergence of the junction leak current.

Although the embodiment of the present invention has been described as above referring to the drawings, it is to be understood that the embodiment is merely exemplarily described, and that various other arrangements may be adopted.

To cite a few examples, the epitaxial layer 124 may be deposited after the formation of the first insulating layer 120, which is an offset sidewall, and then the formation of the second insulating layer 122 may follow.

Also, the first source/drain region 126 or the second source/drain region 128 may be first formed, and then the epitaxial layer 124 may be formed on those source/drain regions.

It is apparent that the present invention is not limited to the above embodiment, and may be modified and changed without departing from the scope and spirit of the invention.

What is claimed is:

1. A method of manufacturing a semiconductor device, comprising:
forming a trench at a predetermined position on a surface of a semiconductor substrate,
forming an isolation layer so as to fill said trench, and so as to protrude from said surface of said semiconductor substrate,
forming a film so as to cover said semiconductor substrate and said isolation layer,
selectively removing said film thus to form a cover layer on a lateral portion of said isolation layer exposed on said semiconductor substrate,
forming a gate electrode unit on said semiconductor substrate,
forming an epitaxial layer in a region between said cover layer and said gate electrode unit on said surface of said semiconductor substrate, and
forming a silicide layer at least on a part of said epitaxial layer.

2. The method according to claim 1,
wherein said forming said gate electrode unit includes:
forming a gate electrode on said semiconductor substrate,
forming an insulating layer on said semiconductor substrate and then performing an etch-back process on said insulating layer so as to form a sidewall on a lateral portion of said gate electrode.

3. The method according to claim 1,
wherein said forming said epitaxial layer includes forming said epitaxial layer to be lower in height from said surface of said semiconductor substrate than a height of said cover layer from said surface of said semiconductor substrate.

4. The method according to claim 1,
wherein said film contains Si and N.
